(19) United States
(12) Patent Application Publication
(10) Pub. No.: US 2022/0120712 A1
(43) Pub. Date: Apr. 21, 2022

(54) DEFECT INSPECTION APPARATUS USING AN EDDY CURRENT AND SEMICONDUCTOR DIE BONDING EQUIPMENT USING THE SAME

(71) Applicant: SK hynix Inc., Gyeonggi-do (KR)

(72) Inventor: Jung Bum WOO, Gyeonggi-do (KR)

(21) Appl. No.: 17/328,056

(22) Filed: May 24, 2021

(30) Foreign Application Priority Data
Oct. 19, 2020 (KR) 10-2020-0135270

(51) Int. Cl. G01N 27/90; G01R 31/28; H01L 23/00

(52) U.S. Cl. CPC G01N 27/9006; H01L 23/562; G01R 31/2896

(57) ABSTRACT

A defect inspection apparatus may include a sensor block, a measuring block, a controller and a storage. The Sensor block may include a plurality of sensors arranged in a zigzag pattern to induce an eddy current to the semiconductor die. The measuring block may be configured to apply an oscillation signal of a set frequency to the sensor block and to receive a change in the set frequency of the oscillation signal. The controller configured to determine whether or not the semiconductor die includes a defect based on the change in the set frequency of the oscillation signal. The storage configured to store the change in the set frequency of the oscillation signal caused by the eddy current in the semiconductor die and position information of the defect in the semiconductor die.

### CROSS-REFERENCES TO RELATED APPLICATION

The present application claims priority under 35 U.S.C. § 119(a) to Korean application number 10-2020-0135270, filed on Oct. 19, 2020, in the Korean Intellectual Property Office, which is incorporated herein by reference in its entirety.

### BACKGROUND

### 1. Technical Field

Various embodiments of the present disclosure generally relate to a defect inspection apparatus using an eddy current for detecting a defect of a semiconductor die or a wafer in semiconductor fabrication processes, and a semiconductor die bonding equipment using the defect inspection apparatus.

### 2. Related Art

A wafer on which a test may be performed may be cut to form a plurality of semiconductor dies. Each of the semiconductor dies may be packaged to form a semiconductor package. In cutting the wafer and packaging the semiconductor dies, a physical defect such as a crack may be generated at the semiconductor die or the wafer. In order to reduce fails of the semiconductor package and a stack package and prevent a shipping of the failed semiconductor package, it may be required to detect the physical defect such as the crack in real time during the packaging process.

### SUMMARY

In an embodiment of the present disclosure, A defect inspection apparatus may include a sensor block, a measuring block, a controller and a storage. The Sensor block may include a plurality of sensors arranged in a zigzag pattern to induce an eddy current to the semiconductor die. The measuring block may be configured to apply an oscillation signal of a set frequency to the sensor block and to receive a change in the set frequency of the oscillation signal. The controller configured to determine whether or not the semiconductor die includes a defect based on the change in the set frequency of the oscillation signal. The storage configured to store the change in the set frequency of the oscillation signal caused by the eddy current in the semiconductor die and position information of the defect in the semiconductor die.

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1 illustrates a defect inspection apparatus according to an embodiment;

FIG. 2 illustrates a sensor block of a defect inspection apparatus according to an embodiment;

FIG. 3 illustrates a semiconductor die bonding equipment with a defect inspection apparatus according to an embodiment;

FIGS. 4A to 4D illustrate a relation between a defect inspection apparatus in a semiconductor die bonding equipment and an object according to an embodiment;

FIG. 5 is a graph showing a change in a frequency of an oscillating signal along a scan direction of a defect inspection apparatus; and

FIG. 6 illustrates a method of inspecting a defect according to an embodiment.

### DETAILED DESCRIPTION

Various embodiments of the present invention will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present invention as defined in the appended claims.

The present invention is described herein with reference to cross-sectional views and/or plane views of idealized embodiments of the present invention. However, the described embodiments of the present invention should not be construed as limiting the inventive concept. Although a few embodiments of the present invention will be shown and described, it will be appreciated by those of ordinary skill in the art that changes may be made in these embodiments without departing from the principles and spirit of the present invention.

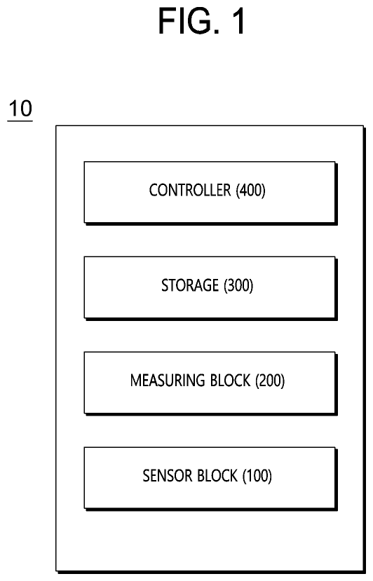

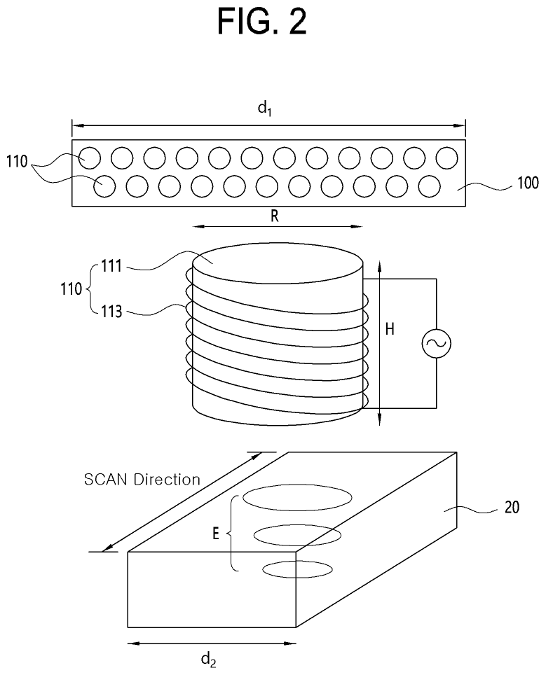

FIG. 1 is a view illustrating a defect inspection apparatus according to an embodiment, and FIG. 2 is a view illustrating a sensor block of a defect inspection apparatus according to an embodiment.

Referring to FIGS. 1 and 2, a defect inspection apparatus 10 of an embodiment may include a sensor block 100, a measuring block 200, a storage 300 and a controller 400. The sensor block 100 may be configured to induce an eddy current to a semiconductor die 20. The measuring block 200 may be configured to apply an oscillation signal having a set frequency to the sensor block 100. The measuring block 200 may be configured to measure a change in frequency of the oscillation signal according to the eddy current generated at the semiconductor die 20. The storage 300 may scan the normal semiconductor die 20 to store information including a reference value set by a changed value of the oscillation signal frequency. The controller 400 may be configured to control a power supply for applying a power to the sensor block 100 and whole operations of the defect inspection apparatus 10.

When a current corresponding to a frequency is applied to the sensor block 100 by the measuring block 200, an eddy current may be induced to the semiconductor die 20. Referring to FIG. 2, the sensor block 100 may include a plurality of sensors 110 arranged in a zigzag shape or pattern. The plurality of sensors 110 may be arranged in a linear shape or other shapes. Each of the sensors 110 may include a body 111 and a coil 113 wound around the body 111. Winding numbers of the coil 113 having a conductive material may be changed according to requirements of the defect inspection apparatus 10.

A total length d1 of the sensor block 100 including the plurality of sensors 110 arranged in the zigzag pattern may be substantially equal to or greater than a width d2 of a semiconductor die 20. For example, the width d2 of the semiconductor die 20 may be substantially perpendicular to a scan direction of the defect inspection apparatus 10 including the sensor block 100. Referring to FIG. 2, the semiconductor die 20 may have a rectangular parallelepiped shape and its upper surface may have a rectangular shape. In this embodiment, the width d2 of the semiconductor die 20 may indicate a relatively smaller side of the semiconductor die 20. The direction of the width d2 is perpendicular to a scan direction of the defect inspection.

For example, the body 111 of each of the sensors 110 may have a Height H (or length) of about 2 mm to about 3 mm and an outer diameter R of about 1 mm to about 1.5 mm, not restricted within a specific value. Further, the winding numbers of the coil 113 may be about 40 to about 50, not restricted within a specific value. That is, the above-mentioned values may be changed according to kinds and states of the semiconductor die 20. FIG. 2 shows that the eddy current E is generated in the semiconductor die 20 by the one sensor 110 but the eddy current E generated in the semiconductor die 20 may be formed by the at least one sensor 110.

The eddy current E may be concentrically formed at the semiconductor die 20 by the sensors 110. When the sensors 110 may be arranged in the zigzag pattern, the eddy current E generated in the semiconductor die 20 by the plurality of sensors 110 may be uniformly formed overall.

The oscillation signal frequency applied to the sensor block 100 may be changed by the eddy current E in the semiconductor die 20. The measuring block 200 may measure a change in the frequency of the oscillation signal. A change in the frequency of the oscillation signal at the semiconductor die 20 without defect may be different from a change in the frequency of the oscillation signal at the semiconductor die 20 with at least one defect. The defect(s) may include physical defects such as a crack, a notch, a scratch, a particle, etc.

The measuring block 200 may apply an alternate current (hereinafter, AC) of a set frequency to the sensor block 100. The measuring block 200 may select any one of a first frequency and a second frequency. The measuring block 200 may apply the AC to the sensor block 100 using the selected frequency. For example, the first frequency may be different from (for example, higher than) the second frequency. For example, the first frequency may be within a range between about 10 MHz and about 20 MHz, i.e., a high frequency. The second frequency may be within a range between about 1 MHz to about 10 MHz, i.e., a low frequency. The measuring block 200 may apply the AC having the first frequency (hereinafter, first AC) to the sensor block 100 and may detect a surface defect of the semiconductor die 20. In contrast, the measuring block 200 may apply the AC having the second frequency (hereinafter, second AC) to the sensor block 100 and may detect an inner defect of the semiconductor die 20.

As an example, the frequency including the first frequency and the second frequency may be within a range between about 1 MHz and about 20 MHz. For example, in order to detect the surface defect of the semiconductor die 20, the measuring block 200 may apply the first AC to the sensor block 100. In order to detect the inner defect of the semiconductor die 20, the measuring block 200 may apply the second AC to the sensor block 100. As stated above, the first frequency may be different from (for example, higher than) the second frequency, hence, the first frequency may have a wavelength shorter than a wavelength of the second frequency. Thus, the first AC may be applied to the surface of the semiconductor die 20 and its vicinity. The second AC may be applied into an inner portion of the semiconductor die 20 to a deeper position than the first AC, because the second AC has the wavelength longer than that of the first AC.

Therefore, the surface defect and the inner defect may be selectively detected according to a depth of the semiconductor die 20 by changing the frequency of the AC.

The storage 300 may store the change in the frequency of the oscillation signal, position information of the defect, etc., measured by the measuring block 200. For example, the storage 300 may store information such as a position information of the semiconductor die 20 having defects within a wafer, information about the position of defects in the semiconductor die 20 and the change in the frequency of the oscillation signal due to the defect, etc.

When the defect may be repeatedly detected at a same position in the wafer, the controller 400 may transmit the information in the storage 300 to an operator or a system configured to change conditions of previous processes. The information includes the position information of the repeatedly detected defect and the change in the frequency of the oscillation signal.

In an embodiment, the position information of the defect may be obtained by a scan speed of the defect inspection apparatus 10 on the semiconductor die 20 and a size of the semiconductor die 20, not restricted within a specific manner.

The controller 400 may control the frequency and the current applied to the sensor block 100 by the measuring block 200. The controller 400 may identify as to whether the defect may exist in the semiconductor die 20 or not using the change in the frequency of the oscillation signal received from the measuring block 200. The semiconductor die 20 with the defect may then be discarded. The controller 400 may control the overall operations of the defect inspection apparatus 10 for detecting the defect of the semiconductor die 20.

In an embodiment, in order to determine as to whether the defect may exist in the semiconductor die 20 or not, a reference value may be set by collecting information obtained by scanning the normal semiconductor die 20. The reference value may then be stored in the storage 300. The controller 400 may compare the change in the frequency of the oscillation signal obtained by scanning the semiconductor die 20 using the defect inspection apparatus 10 with the reference value to determine as to whether the defect may exist or not in the semiconductor die 20.

Further, the controller 400 may transmit the information of the defect of the semiconductor die 20 stored in the storage 300 to the control device of the previous process. When the defect may be repeatedly generated at the same position of the semiconductor die 20, the condition of the previous process may be changed to reduce a generation ratio of the defect.

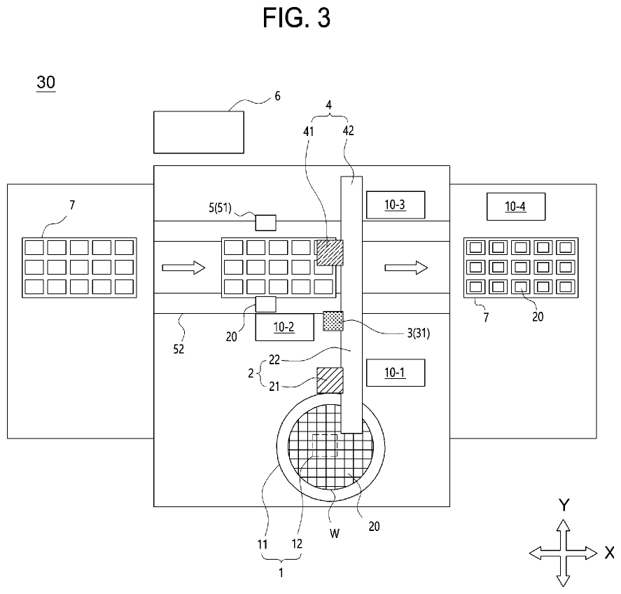

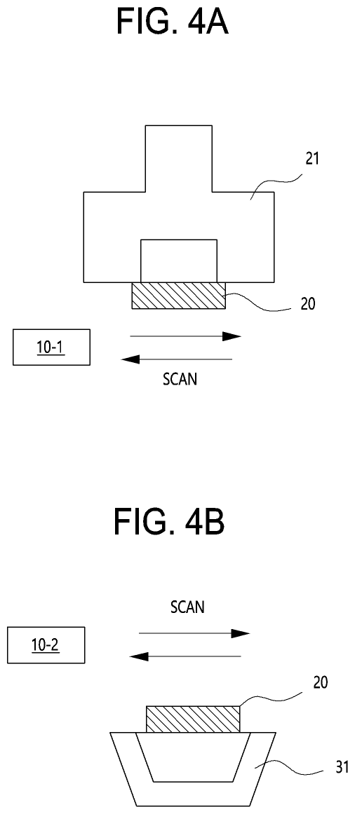

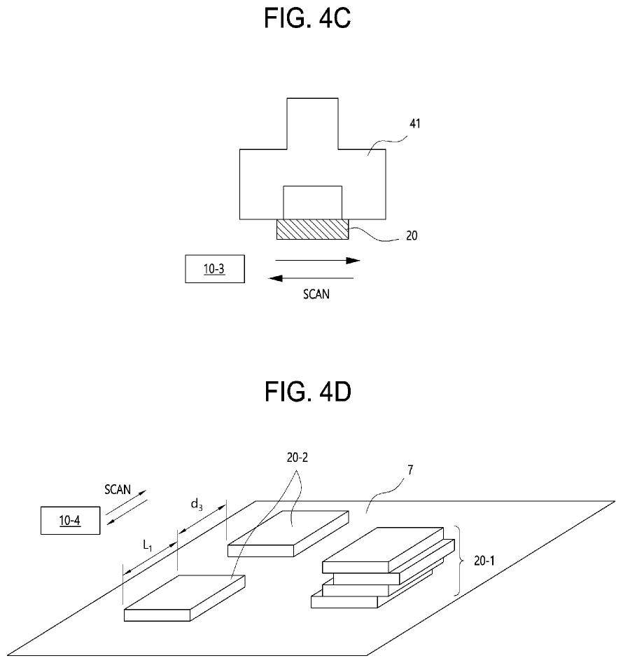

FIG. 3 is a plan view illustrating a semiconductor die bonding equipment with a defect inspection apparatus according to an embodiment, and FIGS. 4A to 4D are views illustrating a relation between a defect inspection apparatus in a semiconductor die bonding equipment and an object according to an embodiment.

A semiconductor die bonding equipment 30 may include a semiconductor die supplier 1, a pick-up module 2, a middle stage module 3, a bonder 4, a substrate transfer 5 and a controller 6. The semiconductor die supplier 1 may be configured to supply the semiconductor die 20 mounted on a package substrate 7. The controller 6 may be configured to control operations of the semiconductor die supplier 1, the pick-up module 2, the middle stage module 3, the bonder 4 and the substrate transfer 5. A Y-direction may be a direction between a front and a rear of the semiconductor die bonding equipment 30. An X-direction may be a direction between a left and a right of the semiconductor die bonding equipment 30. The semiconductor die supplier 1 may be arranged at the front of the semiconductor die bonding equipment 30. The bonder 4 may be arranged in the semiconductor die bonding equipment 30.

Referring to FIGS. 3 and 4A to 4D, the defect inspection apparatus 10 may be provided to at least one of locations where the semiconductor die supplier 1, the pick-up module 2, the middle stage module 3 and the bonder 4 in the semiconductor die bonding equipment 30 are located. However, the defect inspection apparatus 10 is not limited to be provided only at the listed locations above. The defect inspection apparatus 10 may be provided to other apparatuses, for example an apparatus used for fabricating a semiconductor device to monitor as to whether a defect may exist or not in the semiconductor die 20.

The semiconductor die supplier 1 may supply the semiconductor die 20 to be mounted on the package substrate 7. The semiconductor die supplier 1 may include a wafer supporter 11 and a lifter 12. The wafer supporter 11 may be configured to support the wafer W. The lifter 12 may be configured to lift the semiconductor die 20 to be picked-up from the wafer W. The semiconductor die supplier 1 may be moved in the X and Y directions by an actuator. The semiconductor die supplier 1 may move the semiconductor die 20 to a position of the lifter 12.

The pick-up module 2 may include a pick-up head 21 and a driving unit 22. The pick-up head 21 may be configured to pick-up the semiconductor die 20. The driving unit 22 may be configured to move the pick-up head 21. The pick-up head 21 may pick-up the semiconductor die 20 lifted by the semiconductor die supplier 1.

As shown in FIG. 4A, a first defect inspection apparatus 10- may be installed at the pick-up module 2. The first defect inspection apparatus 10-1 may be positioned below the pick-up head 21. The pick-up head 21 may pick up the semiconductor die 20 to detect whether there is a defect in a non-contact manner under the semiconductor die 20.

When a defect is detected by the first defect inspection apparatus 10-1, the semiconductor die 20 with the defect may be immediately discarded without moving to the middle stage module 3. In contrast, when a defect is not detected by the first defect inspection apparatus 10-1, the pick-up head 21 may then move the semiconductor die 20.

The middle stage module 3 may include a middle stage 31 and a stage vision camera. The middle stage 31 may be configured to temporarily load the semiconductor die 20. The stage vision camera may be arranged at an upper portion of the middle stage 31 to identify the semiconductor die 20.

As shown in FIG. 4B, a second defect inspection apparatus 10-2 may be installed at the middle stage module 3. The second defect inspection apparatus 10-2 may be positioned at an upper portion of the middle stage 31 to detect a defect of the semiconductor die 20 in a non-contact manner.

When a defect is detected by the second defect inspection apparatus 10-2, the semiconductor die 20 may be immediately discarded without being subjected to a bonding process. In contrast, when a defect is not detected by the defect inspection apparatus 10-2, the semiconductor die 20 without a defect may be transferred to the bonder 4 to perform a bonding process. And then the semiconductor die 20 may be bonded to the package substrate 7 by the bonder 4.

The bonder 4 may pick-up the semiconductor die 20 on the middle stage 31. The bonder 4 may bond the semiconductor die 20 to the package substrate 7 or stack the semiconductor dies 20 on the semiconductor die 20 bonded to the package substrate 7. The bonder 4 may include a bonding head 41, an actuator 42 and a substrate vision camera. The actuator 42 may be configured to drive the bonding head 41. The substrate vision camera may be configured to identify a bonding position. The actuator 42 of the bonder 4 and the driving unit 22 of the pick-up module 2 may be integrally configured. The actuator 42 and the driving unit 22 may provide a driving force to the bonder 4 and the pick-up module 2, respectively.

As shown in FIG. 4C, a third defect inspection apparatus 10-3 may be installed at a lower portion of the bonding head 41. When the bonding head 41 picks-up the semiconductor die 20 on the middle stage 31, the defect inspection apparatus 10-3 installed at the below the bonding head 41 may detect a defect of the semiconductor die 20 by the third defect inspection apparatus 10-3.

When a defect is detected by the third defect inspection apparatus 10-3, the semiconductor die 20 with the defect may be immediately discarded without moving to the package substrate 7. Alternatively, after transferring the semiconductor die 20 with a defect to the middle stage 31, the semiconductor die 20 may then be discarded in the middle stage 31. However, the discarding of the semiconductor die 20 with a defect might not be restricted by the above-mentioned manners.

As shown in FIG. 4D, a fourth defect inspection apparatus 10-4 may be installed above the package substrate 7. The semiconductor die 20 without a defect is bonded to the package substrate 7. The bonding head 41 may pick-up the semiconductor die 20 on the middle stage 31. The bonding head 41 may bond the semiconductor die 20 to the package substrate 7 or the stacked semiconductor dies 20 bonded to the package substrate 7. After bonding the semiconductor die 20, the fourth defect inspection apparatus 10-4 positioned above the package substrate 7 may detect a defect of the semiconductor die 20. For example, stacked semiconductor dies 20-1 and semiconductor dies 20-2 are horizontally mounted on the package substrate 7. When a defect of the stacked semiconductor dies 20-1 on the package substrate 7 is detected by the fourth defect inspection apparatus 10-4, the sensor block 100 may apply a selected frequency to the semiconductor dies 20-1 to detect a defect based on a height of the stacked semiconductor dies 20-1.

Due to a space d₃, changes in the frequency of the oscillation signal of the semiconductor dies 20-2 may be generated. The fourth defect inspection apparatus 10-4 may include a storage, too. Since the storage of the fourth defect inspection apparatus 10-4 may include information of the space and information of the semiconductor dies 20-2 through the first to third defect inspection apparatus 10-1 to 10-3, the fourth defect inspection apparatus 10-4 may distinguish the changes in the frequency of the oscillation signal caused by the defect of the semiconductor dies 20-2 and the space d₃. (However, the change caused by the space d₃ may be distinguished from the change in the frequency of the oscillation signal caused by the defect in the storage 300.) Alternatively, the fourth defect inspection apparatus 10-4 may detect the change in the frequency of the oscillation signal during a scan time corresponding to a length L1 of the semiconductor die 20-2. In contrast, the fourth defect inspection apparatus 10-4 may not detect the change in the frequency of the oscillation signal during a scan time of the space d₃ between the semiconductor dies 20-2.

When a defect in at least one of the semiconductor dies 20- 2 and the stacked semiconductor dies 20-1 is detected by the fourth defect inspection apparatus 10-4, the package substrate 7 may be discarded. Thus, a packaging of a semiconductor die having defects can be avoided.

Therefore, the defect inspection apparatuses 10-1, 10-2, 10-3 and 10-4 installed in each of the process sections of the semiconductor die bonding equipment 30 may detect a defect of the semiconductor die 20. Thus, for example, a defect of the semiconductor die 20 may be detected before the semiconductor die 20 is bonded to the package substrate 7, by installing the defect inspection apparatuses 10-1, 10-2, 10-3 and 10-4 in each of the process sections. Accordingly, it is possible to reduce the problem of discarding the package substrate 7 on which a plurality of semiconductor dies is mounted.

Generally, in order to determine as to whether the package substrate 7 with the semiconductor die 20 may be normal or not, an electrical test (for example, a probe test) may be performed on the semiconductor die or wafer after performing the semiconductor fabrication processes. However, according to embodiments, the defect inspection apparatuses 10 installed at the pick-up module 2 for performing the pick-up process and the bonder 4 for performing the bonding process may detect defects of the semiconductor die 20 generated in the pick-up process and the bonding process. Thus, when a defect in the semiconductor die 20 is detected, the semiconductor die 20 with the defect may be discarded without bonding the semiconductor die 20 having defects to the package substrate 7. As a result, the semiconductor fabrication processes may be effectively performed.

The substrate transfer 5 may include a transfer head 51 configured to transfer the package substrate 7, and a transfer lane 52 configured to guide the package substrate 7.

The controller 6 may be configured to control the overall operations of the semiconductor die bonding equipment 30.

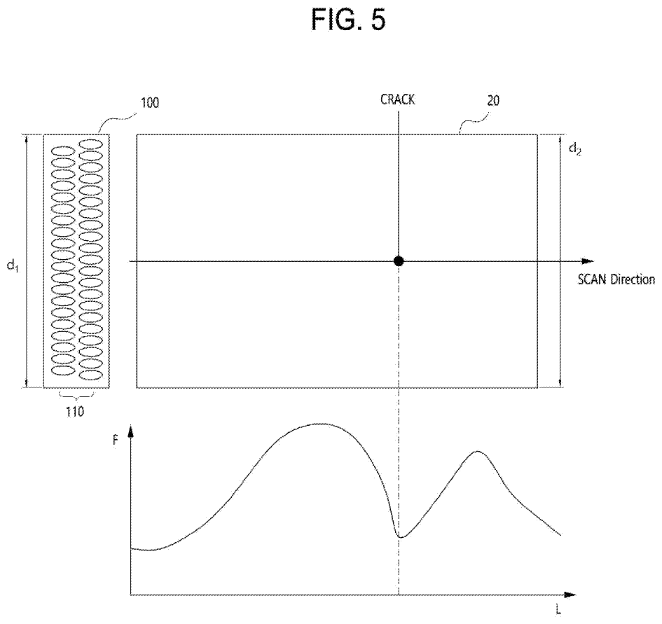

FIG. 5 is a graph showing a change in a frequency of an oscillating signal along a scan direction of a defect inspection apparatus.

Referring to FIG. 5, when the defect inspection apparatus 10 scans a semiconductor die 20 having a defect along a lengthwise direction L of the semiconductor die 20, the defect inspection apparatus 10 may detect the defects of the semiconductor die 20 based on a change in the frequency F of the oscillation signal provided to the sensor block 100.

As mentioned above, the sensor block 100 of the defect inspection apparatus 10 may induce an eddy current to the semiconductor die 20. When a defect exists in the semiconductor die 20 or a difference between materials constituting the semiconductor die 20 may exist, a flow of the eddy current may be changed. The flow change of the eddy current may cause a change in the frequency of the oscillation signal of the sensor block 100 to identify as to whether the defect may exist or not in the semiconductor die 20.

Further, the frequency applied to the sensor block 100 of the defect inspection apparatus 10 may be controlled to detect a defect on the surface of the semiconductor die 20 and a defect in the semiconductor die 20. When stacked semiconductor dies 20 are inspected, the sensor block 100 may selectively control the frequency to detect a defect in each of the stacked semiconductor dies 20.

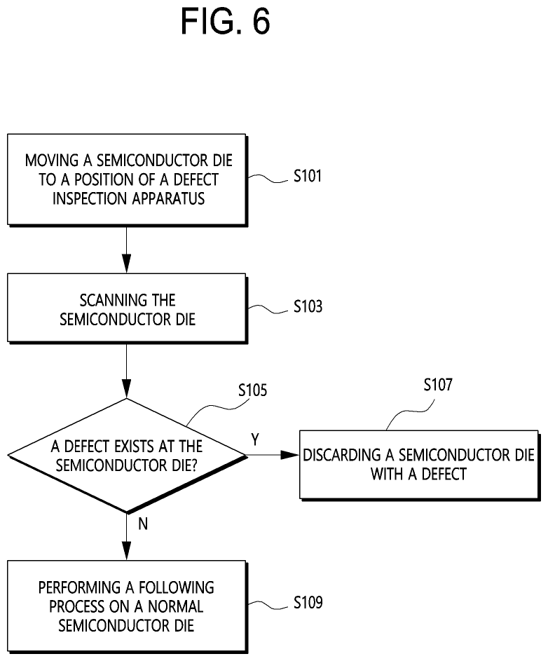

FIG. 6 is a flow chart illustrating a method of inspecting a defect according to example embodiments.

In particular, FIG. 6 illustrates a method for detecting a defect of a semiconductor die after the semiconductor fabrication process and a die sawing are completed.

In operation S101, the semiconductor die 20 may be picked-up in the semiconductor die bonding equipment 30. The semiconductor die 20 may be moved to a position of a defect inspection apparatus 10 by the semiconductor die bonding equipment 30. The defect inspection apparatus 10 may be provided to at least one of the pick-up module 2, the middle stage 3 and the bonder 4 in the semiconductor die bonding equipment 30.

In operation S103, the defect inspection apparatus 10 may be positioned above or below the semiconductor die 20 to scan the semiconductor die 20 in a non-contact manner. The length d1 of the sensor block 100 in the defect inspection apparatus 10 may be substantially equal to or greater than the width d2 of the semiconductor die 20. The defect inspection apparatus 10 may scan the semiconductor die 20 along a direction L substantially perpendicular to the width d2 direction (a length direction) of the semiconductor die 20 to detect a defect. The oscillation signal frequency applied to the sensor block 100 of the defect inspection apparatus 10 may be controlled to detect a defect on or in the semiconductor die 20. The defect inspection apparatus 10 may scan the semiconductor die 20 to generate an eddy current in the semiconductor die 20. The change in the frequency of the oscillation signal applied to the sensor block 100 may be changed based on variations of the eddy current. The reference value of the change in the frequency of the oscillation signal may be set by scanning a defect-free semiconductor die 20.

In operation S105, the change in the frequency of the oscillation signal obtained by scanning the semiconductor die 20 may be compared with the reference value to determine as to whether a defect may exist or not in the semiconductor die 20. When a defect exists in the semiconductor die 20, an amount of the eddy current at the position of the defect may be changed. The measuring block 200 of the defect inspection apparatus 10 may measure the change in the frequency of the oscillation signal according to the variation of the eddy current to determine whether a defect may exist or not in the semiconductor die 20.

When a defect in the semiconductor die 20 is detected, the semiconductor die 20 with a defect may then be discarded in operation S107.

In contrast, when a defect is not detected, the semiconductor die 20 without a defect may be transferred to the following process in operation S109.

The above-described embodiments of the present invention are intended to illustrate and not to limit the present invention. Various alternatives and equivalents are possible. The invention is not limited by the embodiments described herein. Nor is the invention limited to any specific type of a semiconductor device. Other additions, subtractions, or modifications may be made thereto without departing from the scope of the disclosure.

What is claimed is:

1. A defect inspection apparatus for a semiconductor die bonding equipment, the defect inspection apparatus comprising:
a sensor block including a plurality of sensors arranged in a zigzag pattern configured to induce an eddy current to a semiconductor die;
a measuring block configured to apply an oscillation signal of a set frequency to the sensor block and to receive a change in the set frequency of the oscillation signal;
a controller configured to determine whether or not the semiconductor die includes a defect based on the change in the set frequency of the oscillation signal; and
a storage configured to store the change in the set frequency of the oscillation signal caused by the eddy current in the semiconductor die and position information of the defect in the semiconductor die.

2. The defect inspection apparatus of claim 1, wherein the controller is configured to further control the set frequency of the oscillation signal applied to the sensor block by the measuring block to detect the defect on a surface of the semiconductor die and/or the defect in the semiconductor die.

3. The defect inspection apparatus of claim 1, wherein the measuring block is configured to detect the defect on a surface of the semiconductor die by applying an oscillation signal having a first frequency.

4. The defect inspection apparatus of claim 3, wherein the measuring block is configured to detect the defect in the semiconductor die by applying an oscillation signal having a second frequency which is lower than the first frequency.

5. The defect inspection apparatus of claim 3, wherein the first frequency is from about 10 MHz to about 20 MHz.

6. The defect inspection apparatus of claim 4, wherein the second frequency is from about 1 MHz to about 10 MHz.

7. The defect inspection apparatus of claim 1, wherein the semiconductor die bonding equipment comprises:
a pick-up module configured to pick-up the semiconductor die from a wafer;
a middle stage module configured to load the semiconductor die; and
a bonder configured to bond the semiconductor die to the package substrate,
wherein the defect inspection apparatus is provided to at least one of the pick-up module, the middle stage module and the bonder.

8. A semiconductor die bonding equipment, comprising:
a pick-up module configured to pick-up a semiconductor die from a wafer;
a middle stage module configured to load the semiconductor die;
a bonder configured to bond the semiconductor die to a package substrate; and
a defect inspection apparatus provided to at least one of the pick-up module, the middle stage module and the bonder,
wherein the defect inspection apparatus is configured to induce an eddy current in the semiconductor die to detect a defect on a surface or inside of the semiconductor die and includes a sensor block including a plurality of sensors arranged in a zigzag pattern configured to induce the eddy current to the semiconductor die.

9. The semiconductor die bonding equipment of claim 8, wherein the defect inspection apparatus is configured to control a frequency of an oscillation signal applied to the sensor block by a measuring block to detect the defect on the semiconductor die.

10. The semiconductor die bonding equipment of claim 9, wherein the eddy current is generated by the frequency of the oscillation signal applied to the sensor block.

11. The semiconductor die bonding equipment of claim 9, wherein the defect inspection apparatus is configured to detect the defect of the semiconductor die based on a change in the frequency of the oscillation signal and a variation of the eddy current of the semiconductor die.

12. The semiconductor die bonding equipment of claim 8, wherein the defect inspection apparatus is configured to detect the defect on the surface of the semiconductor die using an oscillation signal having a first frequency.

13. The semiconductor die bonding equipment of claim 12, wherein the first frequency is a high frequency of from about 10 MHz to about 20 MHz.

14. The semiconductor die bonding equipment of claim 12, wherein the defect inspection apparatus is configured to detect the defect in the semiconductor die using an oscillation signal having a second frequency that is different from the first frequency.

15. The semiconductor die bonding equipment of claim 14, wherein the second frequency is a low frequency of from about 1 MHz to about 10 MHz.

16. A defect inspection apparatus for detecting a defect of a semiconductor die in a semiconductor die bonding equipment, the defect inspection apparatus comprising:
a sensor block configured to induce an eddy current to the semiconductor die;
a measuring block configured to apply first and second oscillation signals having different first and second frequencies respectively to the sensor block and to receive changes in the first and second frequencies of the first and second oscillation signals;
a controller configured to determine whether or not the semiconductor die includes the defect based on the changes in the first and second frequencies of the first and second oscillation signals and a position of the defect; and
a storage configured to store the changes of the first and second frequencies of the oscillation signals caused by the eddy current in the semiconductor die and position information of the defect in the semiconductor die.
